(19) United States
(12) Patent Application Publication
(10) Pub. No.: US 2021/0407799 A1
(43) Pub. Date: Dec. 30, 2021

(54) WIDE BANDGAP WAFER BACKSIDE CAPPED BY A DETECTION FACILITATING LAYER

(71) Applicant: SEMICONDUCTOR COMPONENTS INDUSTRIES, LLC, Phoenix, AZ (US)

(72) Inventors: Tetsuya YOSHIDA, Ashikaga-shi (JP); Takumi HOSOYA, Oota-shi (JP); Hideto SHIMOYOSHI, Kaizu-shi (JP); Kazuhiro YAMAZAKI, Djiya-shi (JP)

(73) Assignee: SEMICONDUCTOR COMPONENTS INDUSTRIES, LLC, Phoenix, AZ (US)

(21) Appl. No.: 16/948,665

(22) Filed: Sep. 28, 2020

Related U.S. Application Data
(60) Provisional application No. 62/705,462, filed on Jun. 29, 2020.

(51) Int. Cl. H01L 21/02; H01L 21/67

(52) U.S. Cl. CPC H01L 21/02529; H01L 21/67259; H01L 21/0475; H01L 21/0262; H01L 21/02595

(57) ABSTRACT

In one general aspect, an apparatus can include a wide bandgap wafer having a backside and a frontside. The apparatus can include a detection facilitating layer capped on the backside of the wide bandgap wafer, the detection facilitating layer having a thickness less than a thickness of the wide bandgap wafer.

### RELATED APPLICATION

This application claims priority to and benefit of U.S. Provisional Application No. 62/705,462, filed on Jun. 29, 2020, which is incorporated herein by reference in its entirety.

### TECHNICAL FIELD

This description generally relates to wafer detection technologies during semiconductor processing.

### BACKGROUND

Semiconductor wafer processing equipment can be configured to detect a wafer for loading/unloading of the wafer. A sensor, such as an infrared (IR) light-emitting diode (LED) sensor, can be used for wafer detection. However, these sensors may not be configured to detect a wafer made of a wide bandgap (WBG) material.

### SUMMARY

In one general aspect, an apparatus can include a wide bandgap wafer having a backside and a frontside. The apparatus can include a detection facilitating layer capped on the backside of the wide bandgap wafer, the detection facilitating layer having a thickness less than a thickness of the wide bandgap wafer.

In another general aspect, a method can include forming a dielectric layer on a frontside of a wide bandgap wafer, and forming a detection facilitating layer on a backside of the wide bandgap wafer using a chemical formation process.

The details of one or more implementations are set forth in the accompanying drawings and the description below. Other features will be apparent from the description and drawings, and from the claims.

### BRIEF DESCRIPTION OF THE DRAWINGS

FIG. 1 illustrates a wide bandgap (WBG) wafer capped with a polycrystalline silicon carbide (poly-SiC) layer according to an implementation.

FIG. 2 illustrates tool handling of a WBG wafer capped with a detection facilitating layer.

FIGS. 3A through 3I illustrates a process for producing and using a WBG wafer with a detection facilitating layer. s

FIG. 4 illustrates a method for forming a detection facilitating layer.

FIG. 5 illustrates a method of using a tool in connection with a detection facilitating layer.

### DETAILED DESCRIPTION

Semiconductor wafer processing equipment can be configured to detect a wafer for loading/unloading the wafer. A sensor, such as an infrared (IR) light-emitting diode (LED) sensor, can be used for wafer detection. However, these sensors may not be configured to detect a wafer made of a wide bandgap (WBG) material such as Silicon Carbide (SiC), Gallium Nitride (GaN), Gallium Oxide (Ga₂O₃), Aluminum Nitride (AlN), diamond, and/or so forth.

Semiconductor wafer processing equipment can be modified to improve detection of WBG wafers. For example, processing equipment can be equipped with a green color LED sensor, instead of an IR LED sensor, to detect WBG wafers in a desirable fashion. However, updating wafer processing equipment with different types of sensors may be expensive and may not be efficient.

As disclosed herein, a WBG wafer can be capped with detection facilitating layer (also referred to as a detection layer) such as a polycrystalline silicon carbide (poly-SiC) layer. The detection facilitating layer capped on the WBG wafer can facilitate detection of the WBG wafer using processing equipment using a typical IR LED sensor rather than a specialized sensor such as a green color LED sensor.

The capping of a WBG wafer can include, for example chemically forming the detection facilitating layer (e.g., poly-SiC layer) on the WBG wafer. This can include, for example, forming by growing or depositing the detection facilitating layer (e.g., poly-SiC layer) on the WBG wafer.

The capping described herein is different from, and advantageous over, for example, a bonding (e.g., physically bonding) process that can be used to couple a poly-SiC wafer to a WBG wafer. Bonding can include, for example, bonding a single-SiC wafer, which is a type of WBG wafer, that is separate from a poly-SiC wafer to the single-SiC wafer. In other words, in the bonding process, a fully formed single-SiC wafer can be physically bonded to a fully formed poly-SiC wafer. Bonding a poly-SiC wafer to a SiC wafer may be undesirable from a productivity perspective and/or can be limited by bonding process technologies.

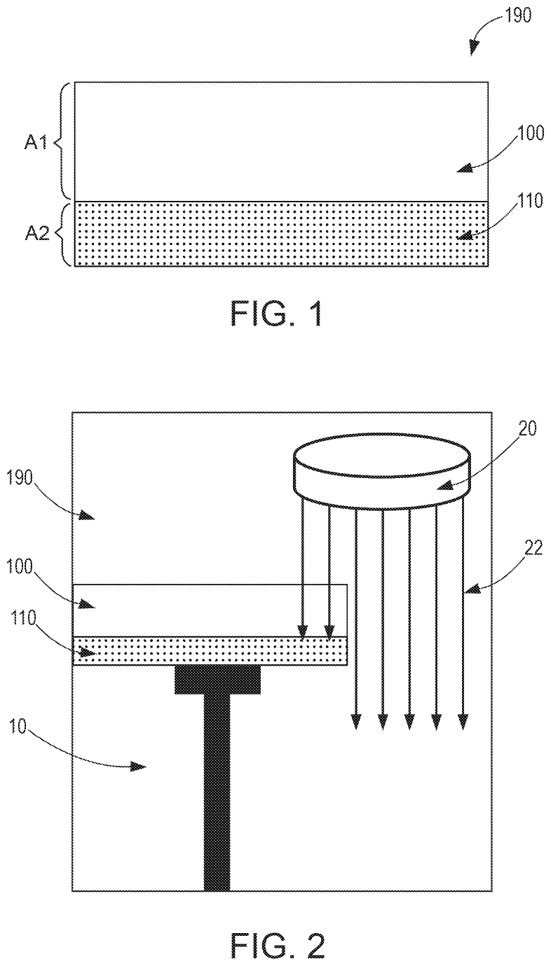

FIG. 1 illustrates a WBG wafer 100 capped (e.g., coupled) with a detection facilitating layer 110 (e.g., a poly-SiC layer). The WBG wafer 100 capped with the detection facilitating layer 110 can be collectively referred to as a capped WBG wafer 190. The WBG wafer 100 can be a SiC wafer, a GaN wafer, a Ga₂O₃ wafer, an AlN wafer, a diamond wafer, and/or so forth. The detection facilitating layer 110 can be coupled to a backside of the WBG wafer 100. Specifically, the detection facilitating layer 110 can be coupled to a side of the WBG wafer 100 that is opposite a side of the WBG wafer 100 where one or more semiconductor elements (e.g., transistor devices, epitaxial layer) will be formed. The semiconductor elements can be formed within and/or on a frontside of the WBG wafer 100.

As shown in FIG. 1, the WBG wafer 100 has a thickness A1 greater than a thickness A2 of the detection facilitating layer 110. In other words, the thickness A2 of the detection facilitating layer 110 is less than the thickness A1 of the WBG wafer 100. In some implementations, the thickness A1 of the WBG wafer 100 can be more than two times greater than the thickness A2 of the detection facilitating layer 110. In some implementations, the thickness A2 of the detection facilitating layer 110 can be at least, or approximately, 1 micrometer.

The capping (e.g., coupling) of the WBG wafer 100 with the detection facilitating layer 110 can be advantageous over bonding of a poly-SiC wafer to a single WBG wafer (e.g., a single SiC wafer). The capping of the WBG wafer 100 with the detection facilitating layer 110 can include, for example, depositing the detection facilitating layer 110 on the WBG wafer 100 using a chemical vapor deposition (CVD) process. The capping of the WBG wafer 100 with the detection facilitating layer 110 can include, for example, forming or growing the detection facilitating layer 110 on the WBG wafer 100. The capping process, which includes formation of the capping layer, for example, on an atomic level by building atomic level layers, is different than a bonding process, which includes coupling whole, separate and full-formed wafers.

Although not shown in FIG. 1, after processing of one or more semiconductor devices within or on the WBG wafer 100 is completed, the detection facilitating layer 110 can be removed. In some implementations, the detection facilitating layer 110 can be removed from the WBG wafer 100 by, for example, a grinding process. In some implementations, the detection facilitating layer 110 can be removed from the WBG wafer 100 by, for example, an etching process.

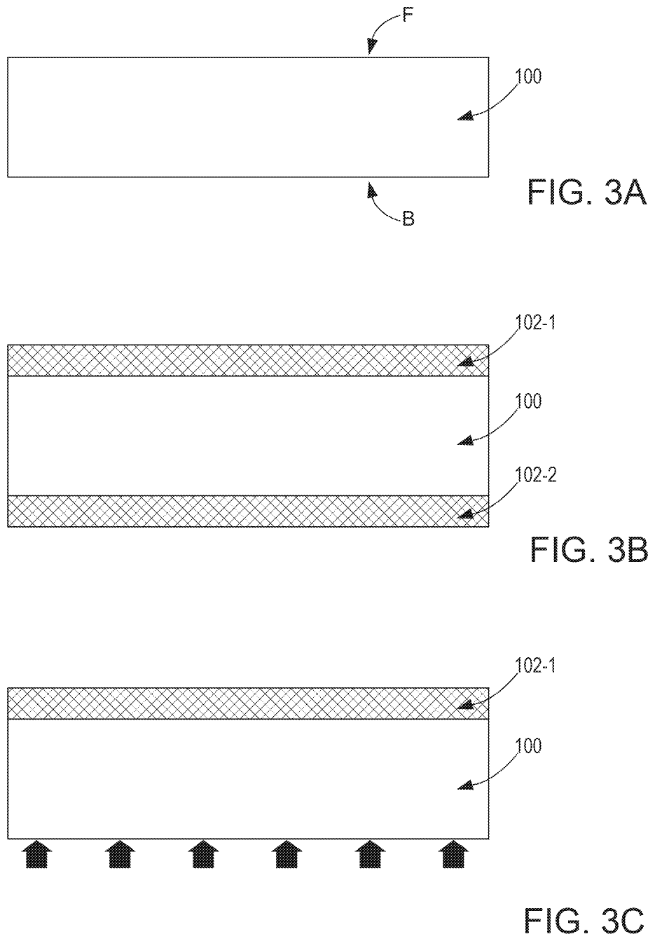

With the detection facilitating layer 110 attached to the WBG wafer 100, the capped WBG wafer 190 can be detected for loading/unloading the capped WBG wafer 190 during the semiconductor processing using a tool 10 as shown in FIG. 2. A sensor, such as an IR sensor 20 as shown in FIG. 2, can be used for wafer detection. As shown in FIG. 2, the IR signals 22 emitted from the IR sensor 20 may penetrate the WBG wafer 100, but do not penetrate the WBG wafer 100. Accordingly, the presence of the WBG wafer 100 can be detected via the detection facilitating layer 110 capped on the WBG wafer 100 in the capped WBG wafer 190.

As shown in FIG. 2, the tool 10 is configured to receive the capped wide bandgap wafer 190 where the capped wide bandgap wafer 190 has a backside (facing the tool) and a frontside (facing the sensor 20). As shown, the capped wide bandgap wafer 190 has the detection facilitating layer 110 capped on the backside of the wide bandgap wafer 100. The sensor 20 is configured to detect that the capped wide bandgap wafer 190 has been received by the tool 10 in response to the signal 22 emitted from the sensor 20. As shown in FIG. 1, the tool 10 is configured to contact the detection facilitating layer 110 of the capped wide bandgap wafer 190.

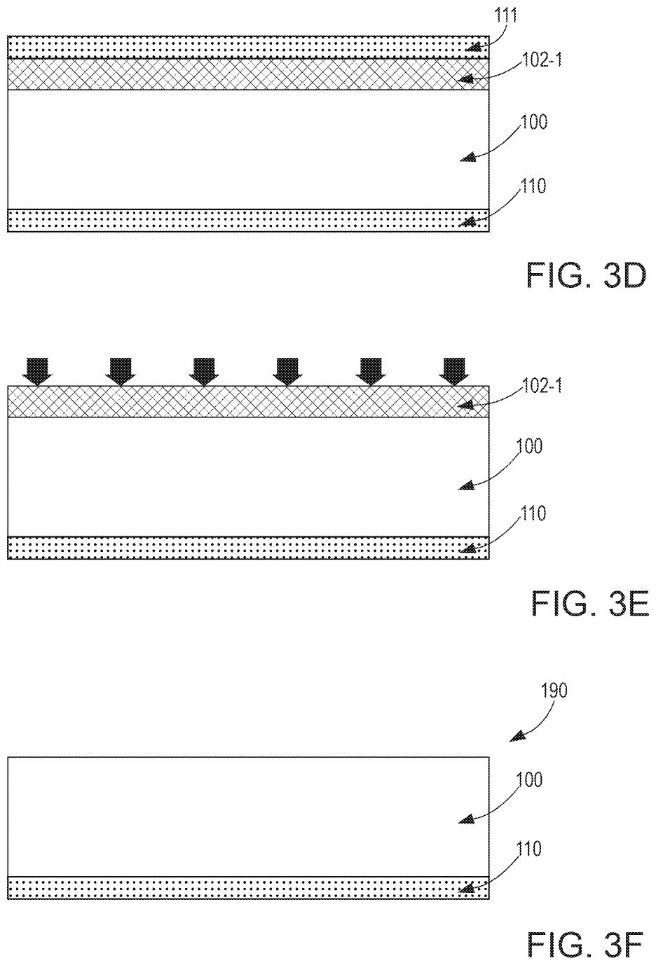

FIGS. 3A through 3I illustrate a process for producing and using a WBG wafer 100 with a detection facilitating layer 110. FIG. 3A illustrates a WBG wafer 100 having a backside B and a frontside F. The WBG wafer 100 can be a SiC wafer, a GaN wafer, a Ga₂O₃ wafer, an AlN wafer, a diamond wafer, and/or so forth.

FIG. 3B illustrates formation of dielectric layers 102 (e.g., dielectric layers 102-1, 102-2) on the WBG wafer 100. Specifically, a dielectric layer 102-1 is formed on the frontside F of the WBG wafer 100 and a dielectric layer 102-2 is formed on the backside B of the WBG wafer 100.

The dielectric layers 102 can be formed using the same process and during the same time period. For example, the dielectric layer 102-1 can be formed using a first process during a first time period and the dielectric layer 102-2 can be formed using the same first process during the same first time period. In some implementations, one or more of the dielectric layers 102 can be a dielectric layer such as an oxide layer.

In some implementations one or more of the dielectric layers 102 can be formed using different processes and/or during different time periods. For example, the dielectric layer 102-1 can be formed using a first process during a first time period and dielectric layer 102-2 can be formed using a second process during a second time period different from the first time period. In some implementations, the dielectric layer 102-1 can be made of a material (e.g., a first type of oxide layer) different from the dielectric layer 102-2 (e.g., a second type of oxide layer).

FIG. 3C illustrates removal of the dielectric layer 102-2 from the backside of the WBG wafer 100. The dielectric layer 102-2, or a portion thereof, can be removed using, for example, a dry etch process. In some implementations, the dielectric layer 102-2, or a portion thereof, can be removed using a grinding process.

FIG. 3D illustrates formation of detection facilitating layers (e.g., detection facilitating layers 111, 110) on the WBG wafer 100. Specifically, a detection facilitating layer 111 is formed on the dielectric layer 102-1 on the frontside F of the WBG wafer 100 and a detection facilitating layer 110 is formed on (e.g., directly on) the backside B of the WBG wafer 100. The detection facilitating layers can be formed using the same process. The detection facilitating layer 111 can be a sacrificial detection facilitating layer that will be removed.

FIG. 3E illustrates removal of the detection facilitating layer 111 from the frontside F of the WBG wafer 100. The detection facilitating layer 111 can be removed using a dry etch process. In some implementations, the detection facilitating layer 111 can be removed using a wet etch process. In such implementations, although not shown, a photo-resist layer can be applied to the detection facilitating layer 110 to prevent (e.g., block) removal of the detection facilitating layer 110 during the wet etch process.

In some implementations, the detection facilitating layer 111 can be removed using a grinding process. In some implementations, the detection facilitating layer 110 can be formed using a process that does not form the detection facilitating layer 111.

FIG. 3F illustrates removal of the dielectric layer 102-1 from the frontside F of the WBG wafer 100 using a wet etch process. The wet etch process removes the dielectric layer 102-1 without removing the detection facilitating layer 110. In other words, the etch process selectively removes the dielectric layer 102-1 without removing the detection facilitating layer 110. After removal of the dielectric layer 102-1, the capped WBG wafer 190 is formed. The capped WBG wafer 190 is the combination of the detection facilitating layer 110 and the WBG wafer 100.

After the capped WBG wafer 190 is formed as shown in FIG. 3F, additional semiconductor processing steps can be performed to form one or more semiconductor elements 120 (e.g., transistors) within or on the WBG wafer 100 as shown in FIG. 3G. FIG. 3G illustrates an activation area 302, a dielectric layer 304, a metal layer 306, and a passivation layer 308. The detection facilitating layer 110 is on a backside of the WBG wafer 100 and is using during processing used to form the one or more semiconductor elements 120.

After the one or more semiconductor elements 120 have been formed, the detection facilitating layer 110 may no longer been needed or used. Accordingly, after the one or more semiconductor elements 120 are formed, the detection facilitating layer 110 can be removed as shown in FIG. 3H. The removal can be performed using, for example, a grinding process. After the semiconductor elements 120 have been formed, the detection facilitating layer 110 may not be needed to detect the WBG wafer 100.

FIG. 3I illustrates formation of a metal layer 130 on a backside of the WBG wafer 100. The metal layer 130 can be formed where the detection facilitating layer 110 was previously coupled to the WBG wafer 100.

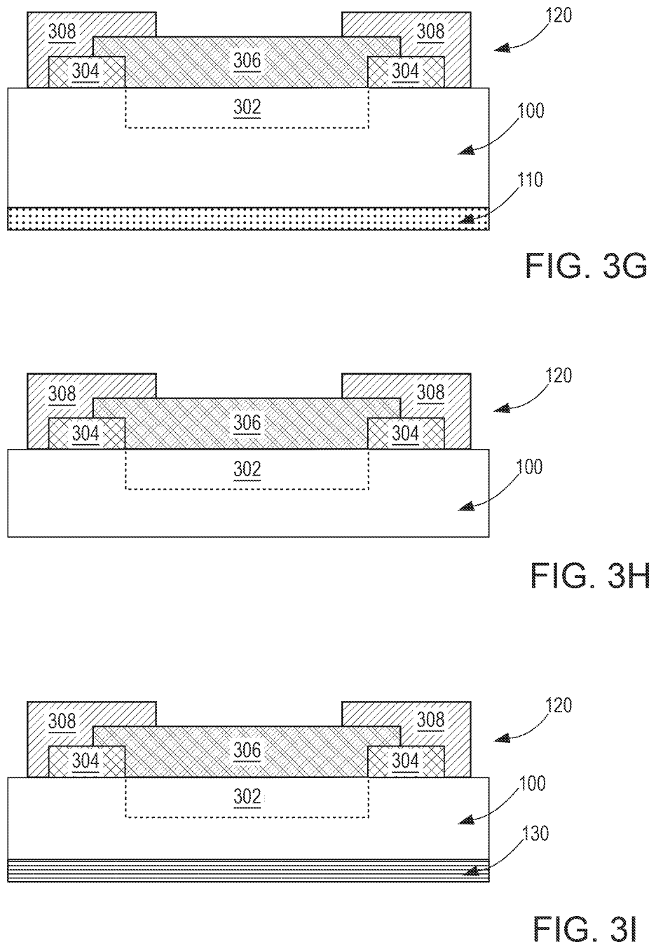

FIG. 4 illustrates a method for forming a detection facilitating layer. As shown in FIG. 4, a method includes forming a dielectric layer on a frontside of a wide bandgap wafer (block 410). The method also includes forming a detection facilitating layer on a backside of the wide bandgap wafer using a chemical formation process (block 420). In some implementations, the detection facilitating layer has a thickness less than a thickness of the wide bandgap wafer. In some implementations, the forming the detection facilitating layer includes forming using a chemical vapor deposition process.

In some implementations, the dielectric layer is a first dielectric layer, and the method also includes forming a second dielectric layer on the backside of the wide bandgap wafer, and removing the second dielectric layer from the backside of the wide bandgap wafer using an etch process.

In some implementations, the method can include removing the dielectric layer from the frontside of the wide bandgap wafer, and forming a semiconductor element at least one of within or on the frontside of the wide bandgap wafer. In some implementations, the method can include removing the polycrystalline SiC layer from the wide bandgap wafer after the forming of the semiconductor element is completed.

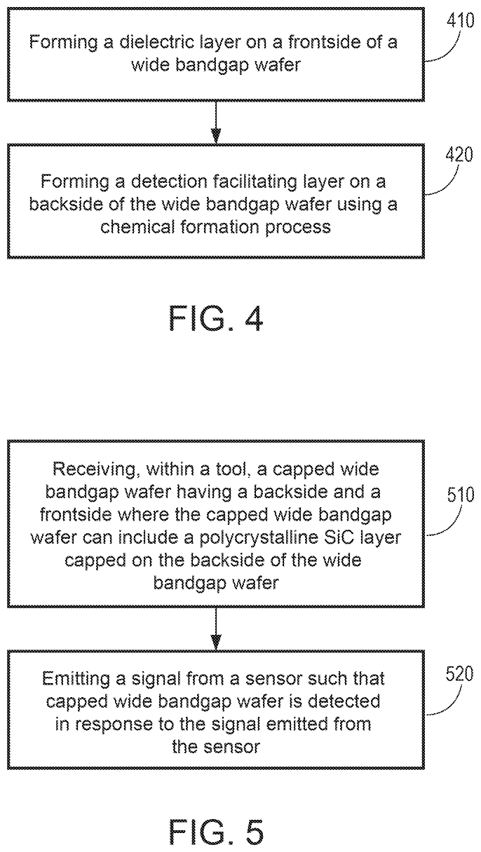

FIG. 5 illustrates a method of using a tool in connection with a detection facilitating layer. The method can include receiving, within a tool, a capped wide bandgap wafer having a backside and a frontside where the capped wide bandgap wafer can include a polycrystalline SiC layer (e.g., a detection facilitating layer) capped on the backside of the wide bandgap wafer (block 510). The method can include emitting an infrared signal from a sensor such that capped wide bandgap wafer is detected in response to the infrared signal emitted from the sensor (block 520). In some implementations, the signal is an infrared signal and the sensor is an infrared sensor.

It will be understood that, in the foregoing description, when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Implementations of the various techniques described herein may be implemented in (e.g., included in) digital electronic circuitry, or in computer hardware, firmware, software, or in combinations of them. Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. An apparatus, comprising:
a wide bandgap wafer having a backside and a frontside; and
a detection facilitating layer capped on the backside of the wide bandgap wafer, the detection facilitating layer having a thickness less than a thickness of the wide bandgap wafer.

2. The apparatus of claim 1, wherein detection facilitating layer is a polycrystalline SiC layer.

3. The apparatus of claim 1, wherein the wide bandgap wafer includes at least one of a Silicon Carbide (SiC) wafer, a Gallium Nitride (GaN) wafer, a Gallium Oxide (Ga₂O₃) wafer, an Aluminum Nitride (AlN) wafer, or a diamond wafer.

4. The apparatus of claim 1, wherein the detection facilitating layer has a thickness of at least approximately 1 micrometer.

5. The apparatus of claim 1, wherein the detection facilitating layer is chemically formed on the wide bandgap wafer.

6. The apparatus of claim 1, wherein the detection facilitating layer is not a separate wafer bonded to the wide bandgap wafer.

7. The apparatus of claim 1, wherein one or more semiconductor elements are formed on or within at least a portion of the frontside of the wide bandgap wafer.

8. The apparatus of claim 1, wherein the capping includes depositing the detection facilitating layer using a chemical vapor deposition process.

9. A method, comprising:
forming a dielectric layer on a frontside of a wide bandgap wafer; and
forming a detection facilitating layer on a backside of the wide bandgap wafer using a chemical formation process.

10. The method of claim 9, wherein the detection facilitating layer has a thickness less than a thickness of the wide bandgap wafer.

11. The method of claim 9, wherein the forming the detection facilitating layer includes forming using a chemical vapor deposition process.

12. The method of claim 9, wherein the dielectric layer is a first dielectric layer, the method further comprising:
forming a second dielectric layer on the backside of the wide bandgap wafer; and
removing the second dielectric layer from the backside of the wide bandgap wafer using an etch process.

13. The method of claim 9, further comprising:
removing the dielectric layer from the frontside of the wide bandgap wafer; and
forming a semiconductor element at least one of within or on the frontside of the wide bandgap wafer.

14. The method of claim 13, further comprising:
removing the polycrystalline SiC layer from the wide bandgap wafer after the forming of the semiconductor element is completed.

15. An apparatus, comprising:
a tool configured to receive a capped wide bandgap wafer having a backside and a frontside, the capped wide bandgap wafer having a detection facilitating layer capped on the backside of the wide bandgap wafer; and
a sensor configured to detect that the capped wide bandgap wafer has been received by the tool in response to a signal emitted from the sensor.

16. The apparatus of claim 15, wherein the signal is an infrared signal and the sensor is an infrared sensor.

17. The apparatus of claim 15, wherein the sensor is configured to detect the capped wide bandgap wafer during at least one of loading or unloading the capped wide bandgap wafer.

18. The apparatus of claim 15, wherein the tool is configured to contact the detection facilitating layer of the capped wide bandgap wafer.

19. A method, comprising:
receiving, within a tool, a capped wide bandgap wafer having a backside and a frontside, the capped wide bandgap wafer having a polycrystalline SiC layer capped on the backside of the wide bandgap wafer; and
emitting a signal from a sensor such that capped wide bandgap wafer is detected in response to the signal emitted from the sensor.

20. The method of claim 19, wherein the signal is an infrared signal and the sensor is an infrared sensor.
